(19) United States
(12) Patent Application Publication
(10) Pub. No.: US 2012/0100716 A1
(43) Pub. Date: Apr. 26, 2012

(54) Method to improve reliability (EM and TDDB) with post silylation plasma treatment process for copper damascene structures

(75) Inventors: Ravi Prakash Srivastava, Beacon, NY (US); David Michael Permana, Fishkill, NY (US)

(73) Assignee: Globalfoundries Singapore Pte., Ltd, Singapore (SG)

(21) Appl. No.: 12/925,374

(22) Filed: Oct. 20, 2010

(51) Int. Cl. H01L 21/768

(52) U.S. Cl. 438/675; 257/E21.585

(57) ABSTRACT

A method for semiconductor fabrication includes etching a via and a trench in a dielectric material to yield an etched surface. The dielectric material may have an ultra-low K value (e.g., a K-value of less than or equal to 2.4). The etched surface is then processed with a gas-phase silylation process to yield a silylated surface. The silylated surface is processed with a plasma treatment process to yield a plasma treated surface. The plasma treated surface, in turn, is processed with a dilute hydrofluoric acid before a conductive metal is deposited in the via and the trench. Inclusion of the plasma treatment process reduces hollow metal defects caused by the silylation process and increases reliability of metal interconnects and improves barrier metallization.

### TECHNICAL FIELD

The present disclosure relates generally to the manufacture of semiconductor devices, and more particularly, to a method to improve reliability (EM and TDDB) using a post-silylation plasma treatment process for copper damascene structures.

### BACKGROUND

Silylation is a process that may be used to restore damaged surfaces of a dielectric material during semiconductor device fabrication. However, when used in relatively new technologies, such as copper damascene processes, the silylation process itself may cause other problems.

Accordingly, there is needed a fabrication process that prevents or reduces damage caused by the utilization of a silylation process for repairing/restoring surfaces of dielectric materials.

### SUMMARY

According to an embodiment of the disclosure, a method for semiconductor fabrication includes etching a via and a trench in a dielectric material to yield an etched surface. The dielectric material may have an ultra-low K value (e.g., a K-value of less than or equal to 2.4). The etched surface may then be processed with a gas-phase silylation process to yield a silylated surface. The silylated surface may then be processed with a plasma treatment process to yield a plasma treated surface. The plasma treated surface, in turn, may be processed with a dilute hydrofluoric acid before a conductive metal is placed in the via and the trench.

The foregoing has outlined rather broadly the features and technical advantages of the present disclosure so that those skilled in the art may better understand the detailed description that follows. Additional features and advantages of the present disclosure will be described hereinafter that form the subject of the claims. Those skilled in the art should appreciate that they may readily use the concept and the specific embodiment(s) disclosed as a basis for modifying or designing other structures for carrying out the same or similar purposes of the present disclosure. Those skilled in the art should also realize that such equivalent constructions do not depart from the spirit and scope of the claimed invention in its broadest form.

Before undertaking the Detailed Description below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior uses, as well as future uses, of such defined words and phrases.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIGS. 1A-1C illustrate example semiconductor fabrication steps that may be used with particular embodiments of the disclosure;

FIGS. 2A-2C illustrate a hollow metal phenomena, recognized by the teaching of the disclosure;

FIG. 3 illustrates a process which incorporates a plasma treatment process, according to an embodiment of the disclosure;

FIGS. 4A-4D illustrate the results of the plasma treatment process, according to an embodiment of the disclosure; and

FIGS. 5A-5D illustrate the effect of plasma treatment processing, according to an embodiment of the disclosure.

### DETAILED DESCRIPTION

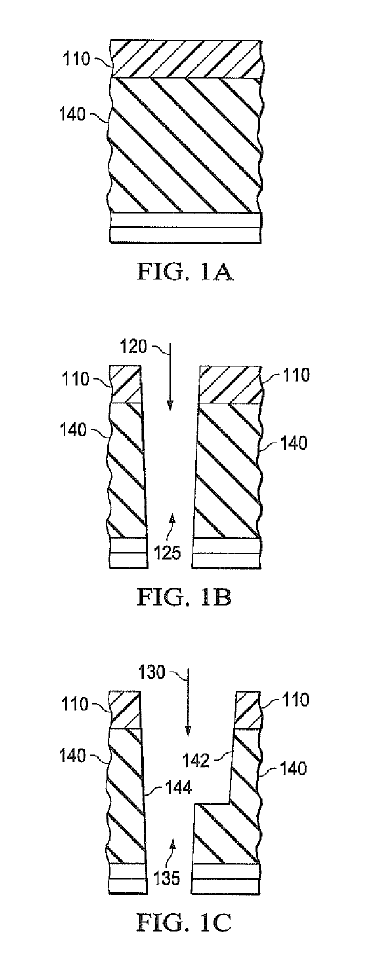

FIGS. 1A through 5D and the various embodiments used to describe the principles of the present disclosure in this patent document are by way of illustration only and should not be construed in any way to limit its scope. Those skilled in the art will understand that the principles described herein may be implemented with any type of suitably arranged device and/or devices.

To simplify the drawings, reference numerals from previous drawings will sometimes not be repeated for structures that have already been identified.

FIGS. 1A-1C illustrate example semiconductor fabrication steps (and portions of a semiconductor device undergoing fabrication) that may be used with particular embodiments. In this particular example, the fabrication is for a damascene structure undergoing what is referred to as a via first trench last (VFTL) process. Although a VFTL process is shown in this example, it should be understood that trench first via last (TFVL) processes and other processes may avail from teaching of this disclosure.

With reference to FIG. 1A, there is shown a portion of a semiconductor device 100 including a layer of ultra low-k (ULK) dielectric material 140 and a hard mask 110 disposed thereabove. The layers 140 and 110 may be disposed above other materials(s). The hard mask 110 may be formed of silicon nitride (SiN), silicon carbide (SiC), or other suitable material.

The ULK dielectric material 140 is considered an “ultra low-k dielectric” because it has a K-value (dielectric constant) of approximately 2.4 or lower. Although particular embodiments will be described with reference to a ULK, it should be understood that utilization of other-than-ULK dielectric materials may benefit from the teachings of the disclosure, such as materials having K-values or dielectric constants of greater than 2.4.

With reference to FIG. 1B, a via 125 is formed in the hard mask 110 and the layer of ULK dielectric material 140 using an etching process 120 or other process that removes selected portions of the layers 110, 140. In particular embodiments, the etching process 120 may be a reactive ion etching (RIE) process or other suitable etching or removal process. In other embodiments, one or more resist layers may be disposed above the ULK dielectric material 140 and/or hard mask 110 to protect the ULK dielectric material 140 and/or the hard mask 110 during the etching process 120.

With reference to FIG. 1C, a trench shaft 135 is formed in the ULK dielectric material 140 and the hard mask 110 using an etching process 130 that may be the same, similar or different from the process 120 described above with respect to FIG. 1B. For example, the etching process 130 in particular embodiments may be a RIE etching process or other suitable etching or removal process. In addition, similar to that described with reference to FIG. 1B, and in some embodiments, one or more resist layers may be disposed above the ULK dielectric material 140 and/or hard mask 130 to protect the ultra-low dielectric material 140 and/or the hard mask 110 during the etching process.

In the fabrication steps described above and shown in FIGS. 1A-1C, sidewalls 144 and 142 (surfaces) of the ULK material 140 may be damaged by the process 120 and/or the process 130. Accordingly, a process known as silylation (also referred to as LKR or Low-K Restoration) may be used in an attempt to restore the damaged surface. After the silylation process, other processes may be performed including a dilute hydrofluoric acid (DHF) clean process.

Although not expressly shown, it is understood that in particular embodiments, copper or other suitable conductive materials will be deposited in the trench 135 and the via 125. Additionally, although only two layers have been shown in FIGS. 1A-1C for purposes of illustration, the semiconductor device 100 may include multiple layers (e.g., multiple inter-level dielectric layers) and the processes described with respect to FIGS. 1A-1C may be repeated as desired.

As described more fully below, when the above-described VFTL/LKR/DHF processes are performed with ULK dielectric material, after metallization within the via/trench, severe hollow metal defects may develop and via yield degradation occurs.

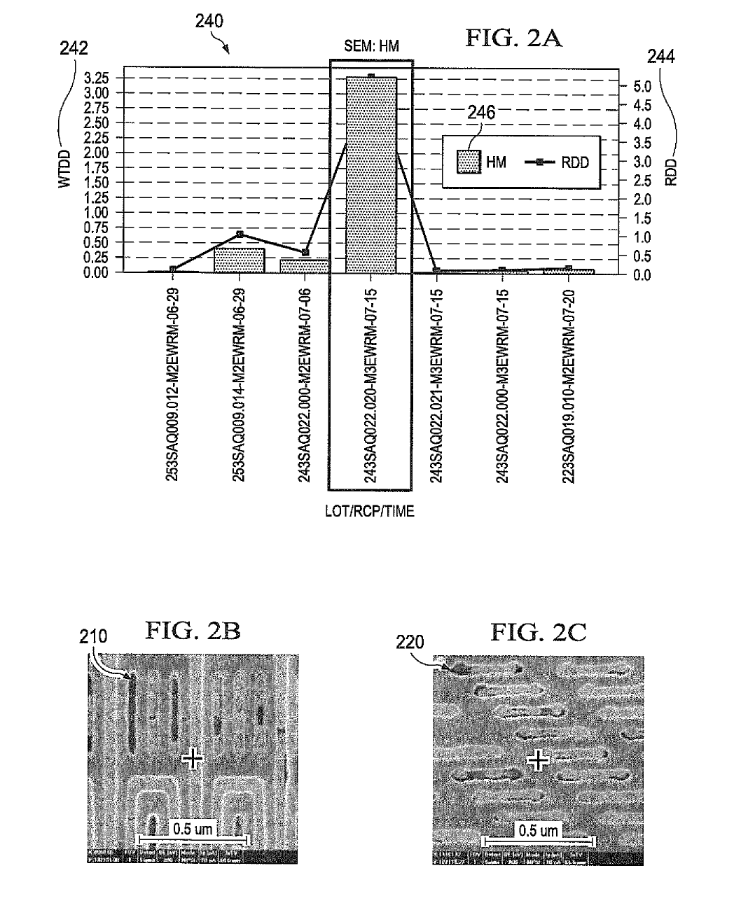

As an illustrative example, within a 32 nm VFTL process using ULK dielectric material, time dependent dielectric breakdown (TDDB) and electro migration (EM) problems have arisen due to ULK dielectric damage. This reduces reliability. To mitigate or correct these problems, a conventional silylation process may be carried out to restore the above-referenced damaged surfaces; however, this results in severe hollow metal defects as illustrated below with reference to FIGS. 2A-2C.

Now turning to FIGS. 2A-2C, there is illustrated the hollow metal defect phenomena caused by the silylation process as recognized by teachings of the disclosure. In particular, the figures illustrate images and data associated with a particular semiconductor device after chemical mechanical polishing (CMP) of copper (damascene) on the semiconductor device.

FIG. 2A is a chart 240 that shows a measure of the hollow metal defect phenomena. For example, HM 246 represents Hollow Metal, RDD 244 represents Random Defect Density, and WTDD 242 represents Weighted Defect Density. The large RDD and WTDD values indicate severity of the hollow metal. In such a chart, one may look at WTDD (weighted defect density) for a determination of the severity of the hollow metal.

FIGS. 2B and 2C include images showing the undesirable hollow metal effect—which are indicated by the dark spots 210, 220 within an etched area. The hollow metal effect may be caused by a variety of factors, including, but not limited to, a smaller critical dimension (CD) of etched areas and the formation of silanol polymers during the silylation process.

Given the above-recited difficulties that can occur in semiconductor fabrications, embodiments of the disclosure describe a process that significantly reduces such the severe hollow metal defects (effect) while simultaneously decreasing TDDM and EM.

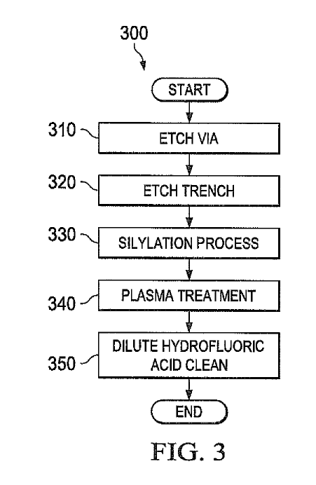

FIG. 3 illustrates a process 300 which incorporates a plasma treatment process, according to an embodiment of the disclosure. Although particular steps will be illustrated, it will be understood that various steps may occur before and after the illustrated steps. Additionally, various intermediate steps are not necessarily described and may also be carried out.

In steps 310 and 320, a via and trench (such as via 125 and trench 135) are formed in the layer and/or layers of materials, which may be a dielectric material. For example, as described with reference to FIGS. 1B-1C, the via 125 and the trench 135 may be formed in the ULK dielectric material 140 (and also in the hard mask 110). In other embodiments, the via and trench may be formed in other-than-ULK-materials, for example, materials having K-values or dielectric constants of greater than 2.4.

Formation of the via 125 and trench 135 in steps 310-320 are performed in a suitable manner using any suitable technique for etching or material removal. In particular embodiments, a reactive ion etching (RIE) process may be utilized. As described with reference to FIGS. 1B-1C, in particular embodiments the hard mask 110 and/or other photoresist materials may be used at the appropriate location.

Although step 310 is shown before step 320, in other embodiments, step 320 may occur before step 310. Additionally, in particular embodiments, step 310 may omitted. And, in other embodiments, step 320 may be omitted.

In step 330, a silylation process is performed to restore damaged surfaces (such as the sidewalls 142, 144, and other surfaces within the trench and via) of the ULK dielectric material 140 that may result from steps 310 and/or 320. Silylation generally involves the introduction of a gas or liquid containing silicon agents, which react with the exposed surfaces and effectively increase the thickness of such exposed surfaces. In particular embodiments, the silylation process of step 330 may be a vapor-phase silylation. Additionally, in particular embodiments the silylation process is not a plasma process.

Example silylating agents include, but are not limited to, hexamethyl disilazane (HMDS), hexamethyl-cyclotrisilazane, trimethylsilyl ethyl isocyanate and/or dimethylsilyldimethylamin, dimethyl silicone, diethyl silicone, phenylmethyl silicone, methylhydrogen silicone, ethylhydrogen silicone, phenylhydrogen silicone, methylethyl silicone, phenylethyl silicone, diphenyl silicone, methyltrifluoropropyl silicone, ethyltrifluoropropyl silicone, polydimethyl silicone, tetrachlorophenylethyl silicone, tetrachlorophenylmethyl silicone, tetrachlorophenylhydrogen silicone, tetrachlorophenylphenyl silicone, methylvinyl silicone and ethylvinyl silicone, and the like.

In step 340, the process 300 includes a plasma treatment process occurring after the silylation process. Although a particular plasma technique and its parameters will be described, the plasma treatment process of step 340 may be used for thin film deposition (e.g., sputtering and plasma-enhanced chemical vapor deposition) or etching. The plasma treatment process of step 340 may work to break silanol polymers and enhance the effectiveness of a subsequent DHF process (step 350).

In particular embodiments, the plasma treatment process of step 340 may be a capacitively coupled plasma treatment process, which is a process recognized by one of ordinary skill in the art.

The gas mixture in the plasma treatment chamber may include CO₂. Additionally, one or more of the following may be used in the gas mixture: CO (carbon monoxide), Ar, He, N₂, H₂, NH₃ or other suitable gases. In particular embodiments, fluorine and/or chlorine are not utilized within the plasma treatment gas mixture. As will be appreciated, in other embodiments, gases that have a small likelihood of damaging the ULK dielectric material may be chosen. The preferred gas mixture CO₂, CO₂/CO and Ar/N₂

In particular embodiments, the plasma may be low to medium density, meaning in a range of 10⁷ to 10¹¹ ions per cubic centimeter.

As will be appreciated, the operating pressure and power for the plasma treatment process may be selected based on the technology, equipment and specific materials utilized. In some embodiments, the plasma may be generated in a chamber having a pressure between about 10 milliTorr and 50 milliTorr, more preferably between about 10 milliTorr to 30 milliTorr. In some embodiments, the source power for the plasma treatment process may be between about 0 watts to 500 watts, and preferably between about 0 watts and 100 watts, using a 60 MHz generator. The bias power may be between about 100 Watts and 500 Watts, and preferably between about 100 watts and 300 watts, using a 13.56 MHz generator.

As referenced above, the plasma treatment process of step 340 breaks silanol polymers that are developed during the prior silylation process. Additionally, in particular embodiments, the plasma treatment process of step 340 may change the ULK dielectric material surfaces (e.g., the top hard mask/trench bottom/via-trench side/copper surface) to a hydrophilic state. This, in turn, may synergistically assist in the DHF process and the ultimate deposition of conductive material such as copper. In particular embodiments, using a low pressure and low bias in the plasma treatment process may allow the critical dimension of the via and trench to be maintained.

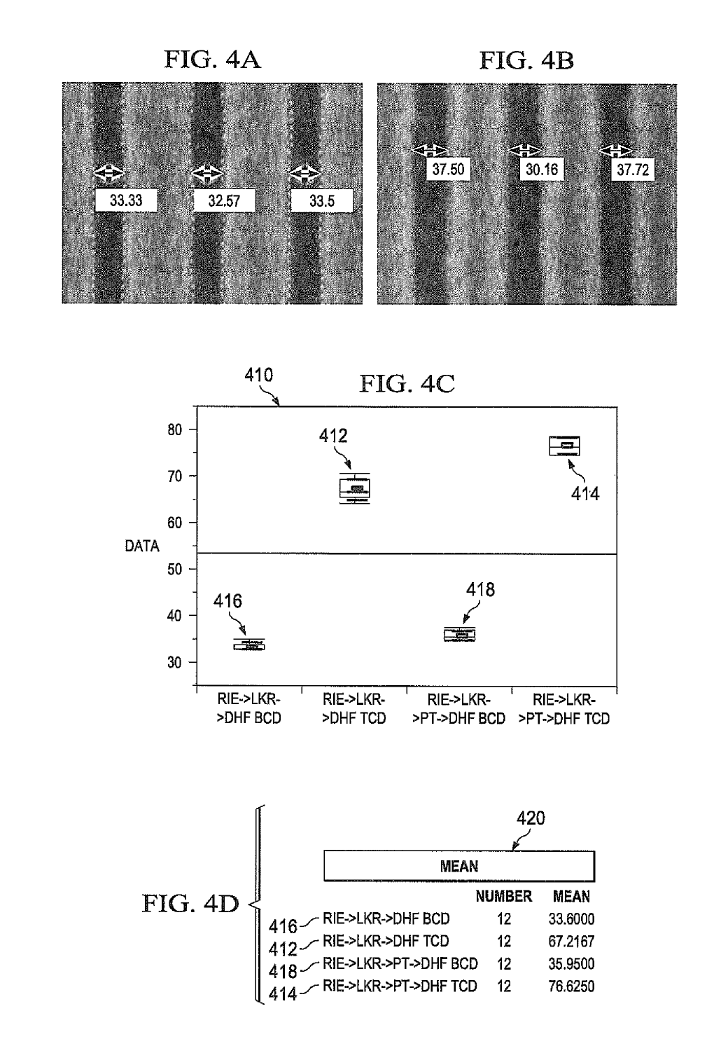

FIGS. 4A-4D illustrates the results of the above-described plasma treatment process, according to an embodiment of the disclosure. FIG. 4A shows distances (33.33, 32.57, 33.5) between bottom critical dimensions of the metalized components (e.g., via/trench) for a semiconductor device that did not undergo the plasma treatment process described in FIG. 3. FIG. 4B shows distances (37.50, 38.16, 37.72) between a bottom critical dimension of the metalized components for the same semiconductor device of FIG. 4B, except this semiconductor device underwent the additional plasma treatment process after a silylation process (e.g., as described in FIG. 3).

FIG. 4C is a chart 410 illustrating how these critical dimension of metalized components have increased as a result of the plasma treatment process. In particular, the chart 410 includes four data groups. Data groups 412, 414 are a measure of a top critical dimension (TCD) whereas data groups 416, 418 are a measure of a bottom critical dimension (BCD).

Data groups 412 and 416 correspond to a semiconductor device that has undergone reactive ion etching (RIE), silylation processing (LKR), and dilute hydrofluoric acid (DHF) processing. Data groups 414 and 418 show the same type of semiconductor device that has undergone the same processing as groups 412 and 416, except that data groups 414 and 418 have also undergone a plasma treatment (PT) process according to this disclosure.

As illustrated in FIG. 4C, for the top critical dimension (TCD), data group 414 (with PT) shows a shift upward from data group 412 (without PT). Similarly, for the bottom critical dimension (BCD), data group 418 (with PT) shows a shift upward from data group 416 (without PT). Therefore, this chart 410 demonstrates the addition of the plasma treatment process increases spacing on both the bottom critical dimension and the top critical dimension. Additionally, one can see that the bottom critical dimension only increases by 2 nm while the top critical dimension increases by 9-10 nm, which gives a better metal fill.

FIG. 4D shows the gathered stats from the data sets in the chart 410 of FIG. 4C. As seen in the chart 420 of FIG. 4D, for the bottom critical dimension, the spacing on average has increased from 33.6 for group 416 to 35.95 for group 418. Additionally, for the top critical dimension, the spacing on average has increased from 67.2167 for group 412 to 76.625 for group 414.

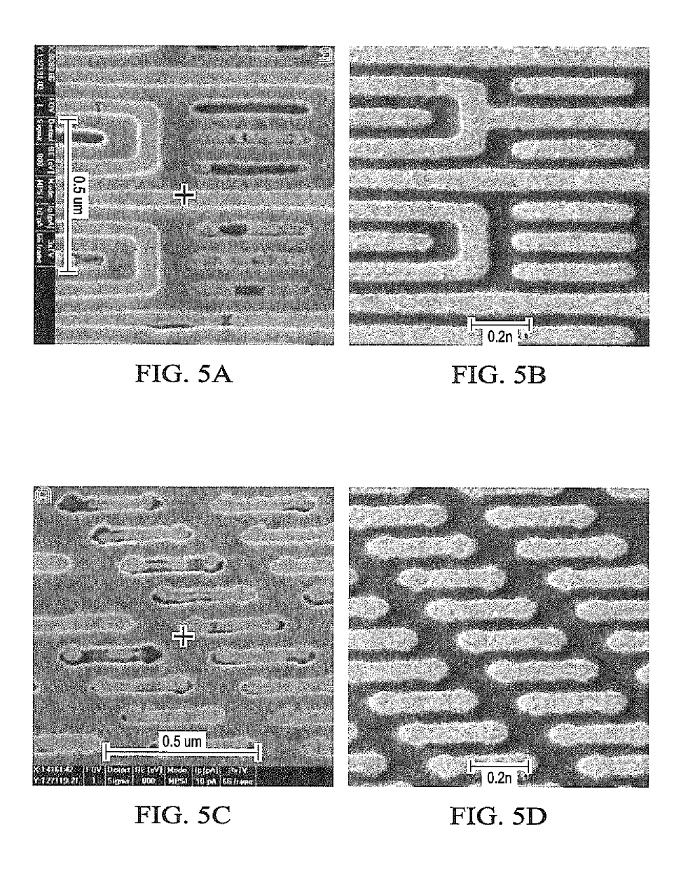

FIGS. 5A-5D are photographs of a semiconductor device which illustrate the effect of the plasma treatment process of the present disclosure. FIGS. 5A and 5C show images of semiconductor devices that have undergone reactive ion etching (RIE), silylation processing (LKR), and dilute hydrofluoric acid (DHF) processing. As can be seen, there are defects (hollow) in the metallization. FIGS. 5B and 5D shows images of semiconductor devices that have undergone the same processing as the semiconductors of FIGS. 5A and 5C, except they have also undergone the plasma treatment process described above. Among other things, one can see the cleaner lines and reduced hollow metal effect when comparing FIG. 5B to FIG. 5A and FIG. 5D to FIG. 5C.

It will be understood that well known processes have not been described in detail and have been omitted for brevity. Although specific steps, structures and materials may have been described, the present disclosure may not be limited to these specifics, and others may substituted as is well understood by those skilled in the art, and various steps may not necessarily be performed in the sequences shown.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

1. A method of semiconductor fabrication comprising:
etching a via and a trench in a dielectric material to yield an etched surface, the dielectric material having a K-value of about 2.4 or less;
processing the etched surface of the material with a gas-phase silylation process to yield a silylated surface; and
processing the silylated surface with a plasma treatment process to yield a plasma treated surface.

2. The method of claim 1, further comprising:
processing the plasma treated surface with a dilute hydrofluoric acid.

3. The method of claim 2, further comprising:
depositing a conductive metal on top of the plasma treated surface in the via and the trench.

4. The method of claim 1, further comprising:
depositing a conductive metal on top of the plasma treated surface in the via and the trench.

5. The method of claim 1, wherein the etching is carried out with a reactive ion etching process.

6. The method of claim 1, wherein the etching is carried out in a via first trench last (VTFL) process.

7. The method of claim 1, wherein the plasma treatment process uses a capacitively coupled plasma technique.

8. The method of claim 1, wherein a gas mixture used in the plasma treatment process includes one or more gases selected from the group consisting of CO, Ar, He, N2, H2, and NH3.

9. The method of claim 1, wherein a gas mixture used in the plasma treatment process lacks fluorine and chlorine.

10. A method of semiconductor fabrication comprising:
processing an etched surface of a material with a silylation process to yield a silylated surface;
processing the silylated surface with a plasma treatment process to yield a plasma treated surface.

11. The method of claim 10, further comprising:
processing the plasma treated surface with a dilute hydrofluoric acid.

12. The method of claim 11, further comprising:
depositing a conductive metal on top of the plasma treated surface.

13. The method of claim 10, wherein the material is a dielectric material having a K-value of about 2.4 or less.

14. The method of claim 10, further comprising:
etching a via and a trench in the material to yield the etched surface.

15. The method of claim 14, wherein
the etching is carried out with a reactive ion etching process.

16. The method of claim 14, wherein
the etching is carried out in a via first trench last (VTFL) process.

17. The method of claim 10, wherein the silylation process is a gas-phase silylation process.

18. The method of claim 10, wherein the plasma treatment process uses a capacitively coupled plasma technique.

19. The method of claim 10, wherein a gas mixture used in the plasma treatment process includes one or more gases selected from the group consisting of CO, Ar, He, N2, H2, and NH3.

20. The method of claim 10, wherein a gas mixture used in the plasma treatment process lacks fluorine and chlorine.

21. The method of claim 1, wherein plasma treatment process is performed at a pressure between about 10 and 50 milliTorr, at a source power of between 0 and 100 watts, and at a bias power of between about 100 and 300 watts.
